(19) United States
(12) Patent Application Publication
(10) Pub. No.: US 2008/0233665 A1
(43) Pub. Date: Sep. 25, 2008

(54) METHOD OF MANUFACTURING A SEMICONDUCTOR DEVICE

(75) Inventors: In-young Jung, Suwon (KR); Choong-youl Im, Suwon (KR); Sung-chul Kim, Suwon (KR)

Correspondence Address: CHRISTIE, PARKER & HALE, LLP, PO BOX 7068, PASADENA, CA, 91109-7068, US

(73) Assignee: SAMSUNG SDI CO., LTD., Suwon-si (KR)

(21) Appl. No.: 11/856,655

(22) Filed: Sep. 17, 2007

(30) Foreign Application Priority Data
Mar. 21, 2007 (KR) 10-2007-0027754

(51) Int. Cl. H01L 21/8242; H01L 33/00

(52) U.S. Cl. 438/23; 438/239; 257/E33.001; 257/E21.646

(57) ABSTRACT

A method of manufacturing a semiconductor device including: forming a semiconductor layer on a substrate with transistor and capacitor formation regions; forming first and second photo resist patterns at the transistor and capacitor formation regions, respectively, the second photo resist pattern having a thickness less than that of the first photo resist pattern; patterning the semiconductor layer using the first and second photo resist patterns as a mask; removing the second photo resist pattern to expose the semiconductor layer at the capacitor formation region; implanting ions in the exposed semiconductor layer to form a first electrode of a capacitor; removing the first photo resist pattern; forming a gate electrode at the transistor formation region; forming an second electrode at the capacitor formatting region; and forming a source region and a drain region at the semiconductor layer formed at both sides of the gate electrode.

### CROSS-REFERENCE TO RELATED APPLICATION

This application claims priority to and the benefit of Korean Patent Application No. 10-2007-0027754, filed on Mar. 21, 2007, in the Korean Intellectual Property Office, the entire content of which is incorporated herein by reference.

### BACKGROUND

1. Field of the Invention

The present invention relates to a method of manufacturing a semiconductor device, more particularly, to a method of manufacturing a semiconductor device including a thin film transistor and a capacitor.

2. Discussion of Related Art

In general, during a procedure of manufacturing a semiconductor device and a flat panel display including the semiconductor device, an insulation layer or a conductive layer is patterned using lithography process and an etch (or etching) process (or lithograph and etch processes). The lithography process forms a photo resist layer pattern that is patterned by exposure and development processes using a mask. The etch process forms an insulation layer or a conductive layer into a certain (or predetermined) pattern using the photo resist layer pattern formed through the lithography process. Here, in more detail, a pattern of the mask is formed by a light transmission blocking material such as chromium (Cr). A non-exposed part of a photo resist layer remains while an exposed part of the photo resist layer is removed by the Cr pattern, so that the photo resist layer pattern is formed.

In a case of a flat panel display including an NMOS thin film transistor (TFT) or a PMOS TFT and a capacitor, different masks are used to form the TFT and the capacitor. This requires a number of masks and process steps. For example, there is a need to have a mask for forming an active layer of the transistor and a lower electrode of the capacitor, another mask for implanting ions into the lower electrode of the capacitor, another mask for forming a gate electrode, another mask for forming source and drain regions, another mask for exposing the source and drain regions, and another mask for forming a source or drain electrode. Accordingly, a manufacturing cost is increased due to the various masks that are needed. In addition, the manufacturing cost is further increased because of a yield reduction due to the many process steps that are needed to be used with the various masks.

### SUMMARY OF THE INVENTION

Aspects of embodiments of the present invention are directed to a method of manufacturing a semiconductor device capable of reducing manufacturing cost by reducing the number of masks and process steps.

An embodiment of the present invention provides a method of manufacturing a semiconductor device. The method includes: forming a semiconductor layer on a substrate with transistor and capacitor formation regions; forming first and second photo resist patterns at the transistor and capacitor formation regions, respectively, the second photo resist pattern having a thickness less than that of the first photo resist pattern; patterning the semiconductor layer using the first and second photo resist patterns as a mask; removing the second photo resist pattern to expose the semiconductor layer at the capacitor formation region; implanting ions in the exposed semiconductor layer to form a first electrode of a capacitor; removing the first photo resist pattern; forming a gate electrode at the transistor formation region; forming a second electrode at the capacitor formatting region; and forming a source region and a drain region at the semiconductor layer formed at both sides of the gate electrode.

### BRIEF DESCRIPTION OF THE DRAWINGS

The accompanying drawings, together with the specification, illustrate exemplary embodiments of the present invention, and, together with the description, serve to explain the principles of the present invention.

FIG. 1 is a circuit diagram for schematically showing an organic light emitting display according to an embodiment of the present invention.

FIG. 2 is a layout for schematically showing the organic light emitting display of FIG. 1.

FIGS. 3A, 3B, 3C, 3D, 3E, 3F, 3G, 3H, and 3I are cross-sectional views for schematically describing a method of manufacturing a semiconductor device according to an embodiment of the present invention.

### DETAILED DESCRIPTION

In the following detailed description, certain exemplary embodiments of the present invention are shown and described, by way of illustration. As those skilled in the art would recognize, the described exemplary embodiments may be modified in various ways, all without departing from the spirit or scope of the present invention. Accordingly, the drawings and description are to be regarded as illustrative in nature, rather than restrictive.

Here, when one element is referred to as being connected to another element, one element may be not only directly connected to the another element but instead may be indirectly connected to the another element via one or more other elements. Also, when an element is referred to as being “on” another element, it can be directly on the another element or be indirectly on the another element with one or more intervening elements interposed therebetween. Further, some of the elements that are not essential to the complete description of the invention have been omitted for clarity. In addition, like reference numerals refer to like elements throughout.

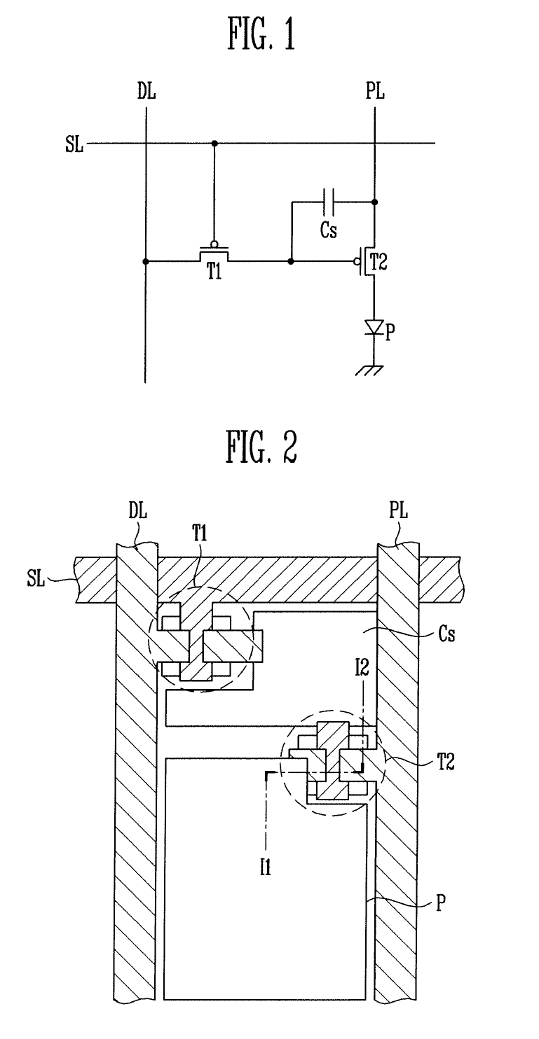

FIGS. 1 and 2 are a circuit diagram and a layout for schematically showing a unit pixel portion of an organic light emitting display according to an embodiment of the present invention.

With reference to FIG. 1 and FIG. 2, the unit pixel portion is defined by a scan line (SL) for selecting a pixel and a data line (DL) for applying a voltage to the pixel. The unit pixel portion includes a switch element T1, a storage capacitor Cs, a driver element T2, and an organic light emitting diode P. The switch element T1 controls a flow of data (e.g., a data voltage) according to a scan line signal. The storage capacitor Cs is charged with a charge by a voltage applied to the data line (DL) and a voltage applied to the power line (PL). The driver element T2 controls an electric current according to an amount of charge stored in the storage capacitor Cs. The organic light emitting diode P emits light by an electric current provided through the driver element T2.

The switch element T1 and the driver element T2 are constructed by an NMOS or PMOS thin film transistor. However, the present invention is not thereby limited. For example, each of the switch element T1 and the driver element T2 can be constructed by a CMOS thin film transistor including NMOS and PMOS thin film transistors.

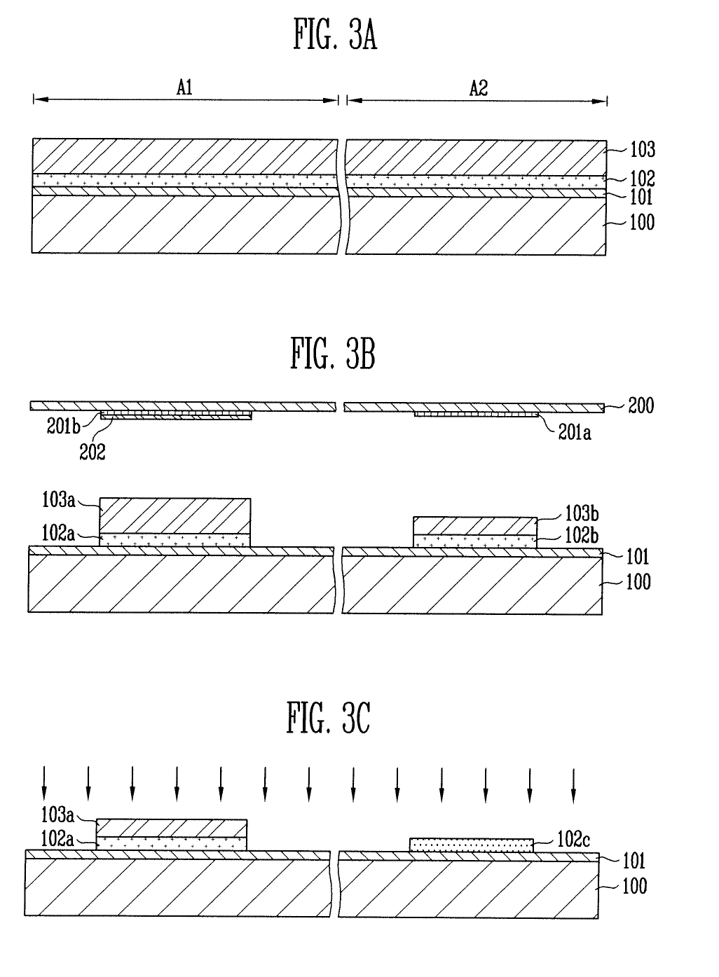

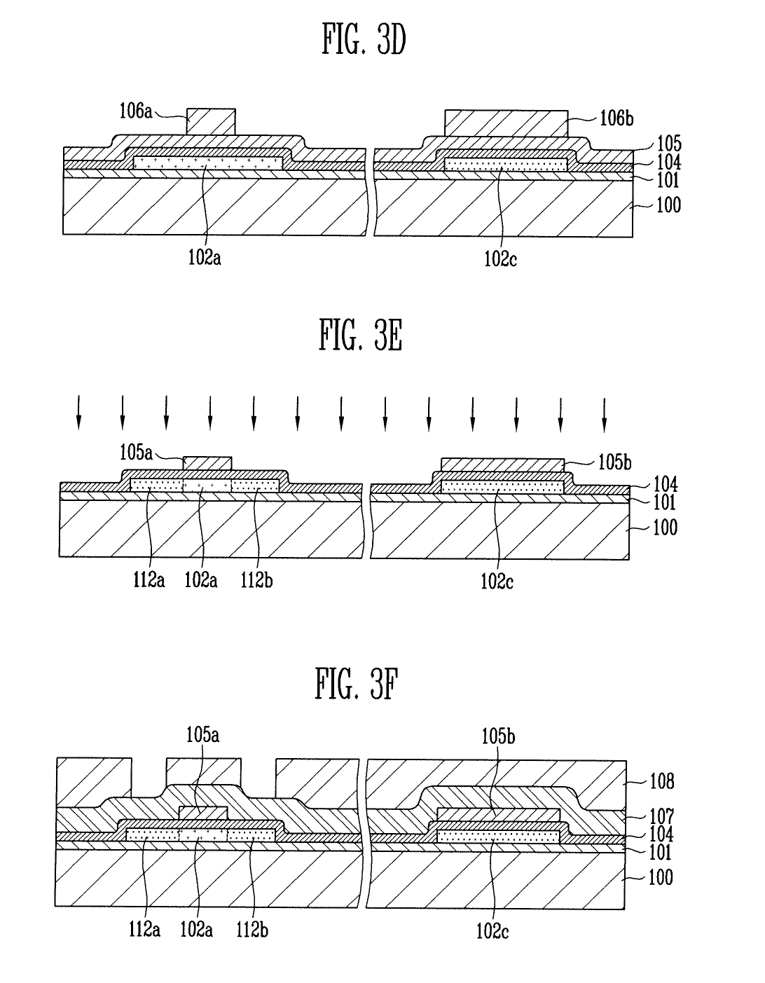

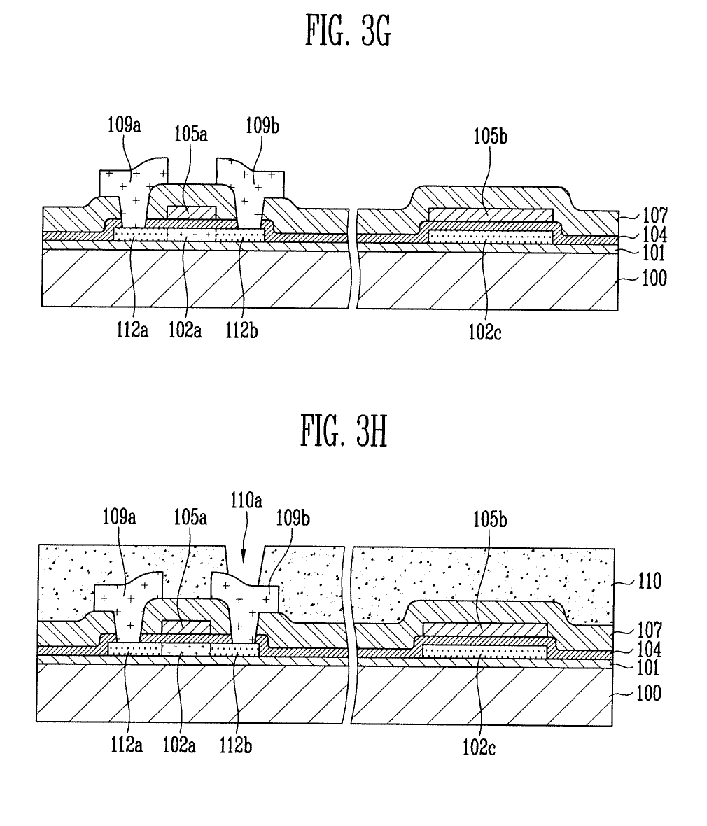

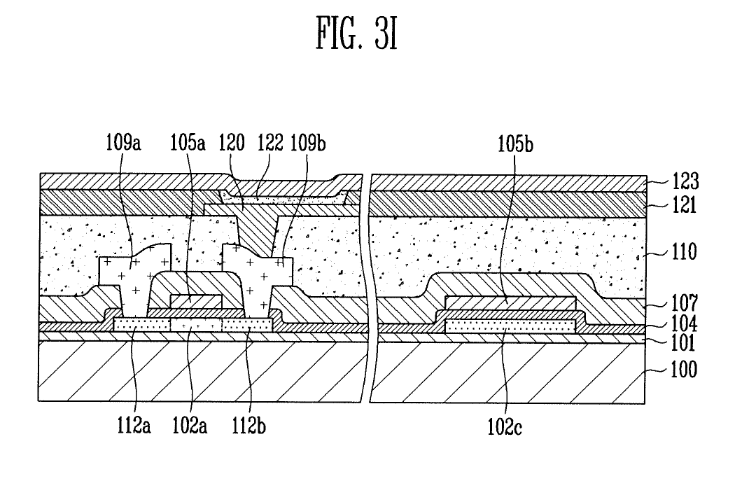

FIG. 3A to FIG. 3I are cross-sectional views for schematically describing a method of manufacturing a semiconductor device according to an embodiment of the present invention. FIG. 3A to FIG. 3I show the driver element T2, a formation region A1 of the organic light emitting diode P, and a formation region A2 of the storage capacitor Cs taken along a line I1-I2 of FIG. 2.

With reference to FIG. 3A, a buffer layer 101, a semiconductor layer 102, and a photo resist layer 103 are sequentially formed, for example, are sequentially formed on a substrate 100. The buffer layer 101 prevents (or protects) the substrate 100 from being damaged due to heat and prevents (or blocks) ions from being diffused from the substrate 100 to an outside of the substrate 100. The buffer layer 101 is formed of an insulation material such as a silicon oxide layer (SiO₂) or a silicon nitride layer (SiNx). The semiconductor layer 102 can be formed by either depositing and crystallizing amorphous silicon or by a relatively low temperature poly silicon process including a laser heat treatment.

With reference to FIG. 3B, by using a mask 200 for forming an active layer of a driver element T2 and a lower electrode of a storage capacitor Cs, the photo resist layer 103 is exposed to light and developed to form a first photo resist layer pattern 103a at a formation region A1 of the driver element T2 and a second photo resist layer pattern 103b at a formation region A2 of the storage capacitor Cs. Here, the second photo resist layer pattern 103b has a thickness less than that of the first photo resist layer pattern 103a, for example, a half of the thickness of the first photo resist layer pattern 103a.

Here, so as to form the first and second photo resist layer patterns 103a and 103b having different thicknesses, a half-tone mask can be used. The half-tone mask includes half-light shielding patterns 201a and 201b, and a light shielding pattern 202 having different transmittances. At least for the parts of which that can transmit light, the half-light shielding patterns 201a and 201b are formed by a material such as MoSi. The light shielding pattern 202 is formed of a material such as chromium (Cr) for intercepting (or blocking) the light. Accordingly, for example, when the half-tone mask 200 (formed by a construction in which the half-light shielding pattern 201a is formed at a part corresponding to a lower electrode of the storage capacitor Cs and the half-light shielding pattern 201a and the light shielding pattern 202 are laminated at a part corresponding to the active layer of the driver element T2) is used, a desired thickness, or only a predetermined thickness, or, in one embodiment, ½ the thickness of the photo resist layer 103 formed at the part corresponding to the lower electrode of the storage capacitor Cs is exposed (e.g., exposed to developing light), but the photo resist layer 103 formed at a part corresponding to the active layer of the driver element T2 is not exposed (e.g., not or not substantially exposed to developing light). This causes the photo resist layer patterns 103a and 103b having different thicknesses to be formed. Here, a thickness of the half-light shielding pattern 201a (and/or pattern 201b) and/or an exposure time is adjusted to change a transmittance degree, so that the thickness of the photo resist layer pattern 103b (and/or pattern 103a) may be controlled.

When the semiconductor layer 102 of an exposed part is removed by an etch process using the first and second photo layer patterns 103a and 103b as a mask, a semiconductor layer 102a having the same (or substantially the same) size as that of the first photo resist layer pattern 103a remains at the formation region A1 of the driver element T2, and the semiconductor layer 102b having the same size as that of the second photo resist layer pattern 103b remains at the formation region of the storage capacitor Cs.

With reference to FIG. 3C, the first and second photo resist layer patterns 103a and 103b are removed to expose the semiconductor layer 102b formed at the formation region A2 of the storage capacitor Cs. Here, an ashing process is performed until the second photo resist layer pattern 103b formed at an upper portion of the semiconductor layer 102b is removed, the first photo resist layer pattern 103a being thicker than the second photo resist layer pattern 103b will partially remain in place.

By an ion implantation process using the remained photo resist layer pattern 103a as a mask, ions are implanted in the exposed semiconductor layer 102b, with the result that a lower electrode 102c of the storage capacitor Cs is formed (and/or completed).

Referring to FIG. 3D, the first photo resist pattern 103a formed at an upper portion of the semiconductor layer 102a is removed, and an insulation film 104 (e.g., a gate insulation film), a conductive layer 105, and a photo resist layer 106 are sequentially disposed at (or on) an entire upper surface including the semiconductor layer 102a and the lower electrode 102c. Here, the conductive layer 105 may be formed by metal such as molybdenum (Mo), tungsten (W), titanium (Ti), aluminum (Al), alloys thereof, and/or laminated structures thereof.

The photo resist layer 106 is exposed to light and developed using a mask for forming a gate electrode of the driver element T2 and a lower electrode of the storage capacitor Cs to form a first photo resist layer pattern 106a at the formation region A1 of the driver element T2 and a second photo resist layer pattern 106b at the formation region A2 of the storage capacitor Cs.

Referring to FIG. 3E, when the semiconductor layer 102 of an exposed part is removed by an etch process using the first and second photo resist layer patterns 106a and 106b as a mask, a gate electrode 105a having the same size as that of the first photo resist layer pattern 106a is formed at the formation region A1 of the driver element T2, and the upper electrode 105b having the same size as that of the second photo resist layer pattern 106b is formed at the formation region of the storage capacitor Cs, with the result that the storage capacitor Cs including the lower electrode 102c, the insulation film (or dielectric substance) 104, and the upper electrode 105b is completed.

Next, in a state that the first and second photo resist layer patterns 106a and 106b are removed or remain, by an ion implantation process using the gate electrode 106a as a mask, ions are implanted in the semiconductor layer 102a formed at both sides of the gate electrode 105a to form source and drain regions 112a and 112b, so that the driver element T2 including the gate electrode 105a, the source and drain regions 112a and 112b is completed.

Referring to FIG. 3F, after an interlayer dielectric 107 and a photo resist layer 108 are formed at an entire upper surface including the formation region A1 of the driver element T2 and the formation region A2 of the storage capacitor Cs, the photo resist layer 108 is exposed to light and developed using a mask to form a photo resist layer pattern 108 with a contact hole (e.g., the mask being for forming the contact hole).

With reference to FIG. 3G, through an etch process using the photo resist pattern 108 as a mask, exposed part(s) of the interlayer dielectric 107 and exposed part(s) of the gate insulation film 104 are etched to form contact hole(s) for exposing certain (or predetermined) parts of the source or drain region 112a or 112b. A conductive layer is then formed at an entire upper surface to bury the contact hole(s). Also, by lithography and etch processes using the photo resist layer, the conductive layer is patterned to form source and drain electrodes 109a and 109b, which are connected to the source and drain regions 112a and 112b through the contact hole(s). Here, the source and drain electrodes 109a and 109b may be formed by metal such as molybdenum (Mo), tungsten (W), titanium (Ti), aluminum (Al), alloys thereof, and/or laminated structures thereof.

Referring to FIG. 3H, a planarizing layer 110 is formed at an entire upper surface of the semiconductor device to planarize the surface. The planarizng layer 110 is patterned by lithography and etch processes using a photo resist layer to form a via hole 110a exposing a certain (or predetermined) part of the source electrode 109a or the drain electrode 109b.

With reference to FIG. 3I, an anode electrode 120 is formed to be connected to the source electrode or the drain electrode through the via hole 110a. After a pixel definition film 121 is formed at an entire upper surface including the anode electrode 120, it is patterned to expose an anode electrode 120 of an emission region. An organic thin film 122 is formed on the exposed anode electrode 120 of the emission region, and a cathode electrode 123 is formed at an entire upper surface including the organic thin film 122. Subsequently, a passivation layer can be formed at an entire upper surface.

As described above, in an embodiment of the present invention, first and second photo resist layer patterns (e.g., patterns 103a and 103b) having different thicknesses are formed at (or on) a formation region (e.g., region A1) of a driver element (e.g., element T2) and a formation region (e.g., region A2) of a storage capacitor (e.g., capacitor Cs) using a half-tone mask (e.g., mask 200) including half-light shielding patterns (e.g., patterns 201a and 201b) and a light shielding pattern (e.g., pattern 202) having different transmittance rates. For example, by using the first and second photo resist layer patterns 103a and 103b having different thicknesses, an active layer of the driver element T2 and a lower electrode of the storage capacitor Cs are formed.

Since one mask is used to perform a process for forming semiconductor layers 102a and 102b at the formation region of the driver element T2 and the formation region of the storage capacitor Cs, and a process is used for implanting ions in the semiconductor layer 102b to form the lower electrode 102c of the storage capacitor Cs, the number of masks and process steps can be reduced.

Also, as a size of a substrate is increased, electric characteristics of a storage capacitor Cs become non-uniform. This problem is caused by a reduction of a capacitance due to a reduction of dose (or implant) amount. So as to solve such a problem, a method for using a metal insulator metal (MIM) capacitor is used. In this case, in order to manufacture MIM capacitor, a mask should be added.

However, in an embodiment of the present invention, because the storage capacitor Cs is formed by doped poly-silicon/insulation film/metal structure, a change in a capacitance according to a dose is small, and it can have relatively good (or excellent) characteristics at a low drive frequency (<100 Hz).

In an embodiment of the present invention, a case of using a positive photo resist layer has been described as an example. However, since embodiments of the present invention are applicable to a case of (and/or formed) using a negative photo resist layer, the present invention is not thereby limited. For example, other embodiments of the present invention can be applicable (and/or formed) using a suitable negative photo resist layer and a suitable mask, and an order of processes can be suitably changed.

As is seen from the foregoing description, photo resist layer patterns having different thicknesses are formed at a formation region of a driver element and a formation region of a storage capacitor by a lithography process using mask patterns having varying transmittance ratios, and an active layer of the driver element and a lower electrode of the storage capacitor are formed using the photo resist layer patterns having different thicknesses. Since one (or only one) mask may be used to perform a process for forming semiconductor layers at the formation region of the driver element and the formation region of the storage capacitor, and a process is used for implanting ions in the semiconductor layer, the number of masks and process steps may be reduced to thereby reduce manufacturing cost and improve the yield.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims and equivalents thereof.

What is claimed is:

1. A method of manufacturing a semiconductor device, the method comprising:
forming a semiconductor layer on a substrate with a transistor formation region and a capacitor formation region;
forming a first photo resist pattern and a second photo resist pattern at the transistor formation region and the capacitor formation region, respectively, the second photo resist pattern having a thickness less than that of the first photo resist pattern;
patterning the semiconductor layer using the first and second photo resist patterns as a mask;
removing the second photo resist pattern to expose the semiconductor layer at the capacitor formation region;
implanting ions in the exposed semiconductor layer to form a first electrode of a capacitor;
removing the first photo resist pattern;
forming a gate electrode at the transistor formation region;
forming a second electrode at the capacitor formatting region; and
forming a source region and a drain region at the semiconductor layer formed at both sides of the gate electrode.

2. The method as claimed in claim 1, wherein, after the removing the first photo resist pattern and before the forming the gate electrode at the transistor formation region and the forming the second electrode at the capacitor formation region, the method further comprises:
forming a gate insulation film, a conductive layer, and a third photo resist layer sequentially on the semiconductor layer at the transistor formation region and the first electrode of the capacitor.

3. The method as claimed in claim 2, wherein the conductive layer comprises a metal selected from the group consisting of molybdenum (Mo), tungsten (W), titanium (Ti), aluminum (Al), alloys thereof, and laminated structures thereof.

4. The method as claimed in claim 2, wherein both the forming the gate electrode at the transistor formation region and the forming the second electrode at the capacitor formation region are performed at substantially the same time using the gate insulation film, the conductive layer, and the third photo resist layer.

5. The method as claimed in claim 1, wherein both the forming the gate electrode at the transistor formation region and the forming the second electrode at the capacitor formation region are performed at substantially the same time.

6. The method as claimed in claim 1, wherein the first and second photo resist patterns are formed by a lithography process using a half tone mask.

7. The method as claimed in claim 1, wherein the first photo resist pattern at the transistor formation region is removed to retain a certain thickness in the removing the second photo resist pattern to expose the semiconductor layer at the capacitor formation region.

8. The method as claimed in claim 1, wherein the first photo resist pattern is used as a mask when the ions are implanted into the semiconductor layer to form the first electrode of the capacitor.

9. The method as claimed in claim 1, wherein the gate electrode and the second electrode are concurrently formed.

10. The method as claimed in claim 1, further comprising:
forming a first insulation film at the transistor formation region and the capacitor formation region to form a first contact hole for exposing the source region and a second contact hole for exposing the drain region;
forming a source electrode and a drain electrode to be connected to the source region and the drain region through the first contact hole for exposing the source region and the second contact hole for exposing the drain region;
forming a second insulation film at the transistor formation region and the capacitor formation region to form a via hole for exposing at least one of the source electrode or the drain electrode; and
forming an organic light emitting display connected to the at least one of the source electrode or the drain electrode through the via hole.

11. The method as claimed in claim 10, wherein the first insulation layer comprises an interlayer dielectric, and wherein the second insulation layer comprises a planarizing layer.

12. The method as claimed in claim 10, wherein the forming the organic light emitting display connected to the source electrode or the drain electrode through the via hole comprises:
forming a first electrode coupled to the at least one of the source electrode or the drain electrode;
forming a third insulation film on the second insulation and the first electrode with a pattern for exposing a part of the first electrode;
forming an organic thin film on the exposed part of first electrode; and
forming a second electrode on the organic thin film.

13. The method as claimed in claim 10, wherein the first insulation layer comprises an interlayer dielectric, wherein the second insulation layer comprises a planarizing layer, and wherein the third insulation layer comprises a pixel definition film.

14. The method as claimed in claim 1, wherein the first and second photo resist patterns are formed by a half tone mask comprising a first half-light shielding pattern, a light shielding pattern, and a second half-light shielding pattern, the first half-light shielding pattern and the light shielding pattern being for forming the first photo-resist pattern, the second half-light shielding pattern being for forming the second photo resist pattern.

15. The method as claimed in claim 14, wherein each of the first half-light shielding pattern and the second half-light shielding pattern is formed from MoSi.

16. The method as claimed in claim 15, wherein the light shielding pattern is formed from chromium (Cr).

17. The method as claimed in claim 1, wherein the first photo resist pattern is formed by a first half-light shielding pattern and a light shielding pattern, and wherein the second photo resist pattern is formed by a second half-light shielding pattern.

18. The method as claimed in claim 1, wherein the first and second photo resist patterns are formed at substantially the same time.

19. The method as claimed in claim 1, wherein the first and second photo resist patterns are concurrently formed.
